(19) United States
(12) Patent Application Publication
(10) Pub. No.: US 2012/0074522 A1
(43) Pub. Date: Mar. 29, 2012

(54) VERTICAL ZENER DIODE STRUCTURE AND MANUFACTURING METHOD OF THE SAME

(76) Inventors: Shuai Zhang, Shanghai (CN); Ke Dong, Shanghai (CN)

(21) Appl. No.: 13/239,245

(22) Filed: Sep. 21, 2011

(30) Foreign Application Priority Data
Sep. 26, 2010 (CN) 201010291813.2

(51) Int. Cl. H01L 29/866; H01L 21/02

(52) U.S. Cl. 257/603; 438/380; 257/E29.335; 257/E21.002

(57) ABSTRACT

The present invention discloses a vertical zener diode structure, in which a deep N-sinker region and a P-implantation region of the zener diode are formed in an N-well within an epitaxial layer; the P-implantation region is closer to a silicon surface than the deep N-sinker region in a vertical direction. In this structure, as zener breakdown occurs at a position away from the silicon surface, the problem of a drift in the zener breakdown value can be improved. The present invention also discloses a manufacturing method of a vertical zener diode.

### CROSS-REFERENCES TO RELATED APPLICATIONS

This application claims the priority of Chinese patent application number 201010291813.2, filed on Sep. 26, 2010, the entire contents of which are incorporated herein by reference.

### TECHNICAL FIELD

The present invention relates to a vertical zener diode structure and its manufacturing method.

### BACKGROUND OF THE INVENTION

A conventional zener diode adopts a structure formed by an N-implantation ring on a silicon surface surrounding a P-implantation region. When the zener diode with the above structure is in a working state, some current carriers will be captured by the silicon surface during the zener breakdown, which will cause a great drift in a zener breakdown value, resulting in reliability problems of the clamping circuit and may even cause the failure of the product.

### SUMMARY OF THE INVENTION

An objective of the present invention is to provide a vertical zener diode structure which can improve the reliability of a zener diode.

To achieve the above goal, the present invention provides a vertical zener diode structure, wherein a deep N-sinker region and a P-implantation region of the zener diode are formed in an N-well within an epitaxial layer; the P-implantation region is closer to a silicon surface than the deep N-sinker region in a vertical direction.

Another objective of the present invention is to provide a manufacturing method of a vertical zener diode, wherein a deep N-sinker region and a P-implantation region of the zener diode are formed in sequence in an N-well within an epitaxial layer; the P-implantation region is formed on the silicon surface and is above the deep N-sinker region.

In the vertical zener diode structure of the present invention, the zener breakdown occurs at a position away from the silicon surface, so that the problem of the drift in the zener breakdown value can be improved and the reliability of the product can be enhanced. Moreover, the structure of the present invention has been used in a BCD process.

### BRIEF DESCRIPTION OF THE DRAWINGS

The present invention will be further detailed in combination with the drawings and embodiments in follows:

FIG. 1 is a schematic diagram of the structure of an existing zener diode;

FIG. 2 is a schematic diagram of the vertical zener diode structure of the present invention;

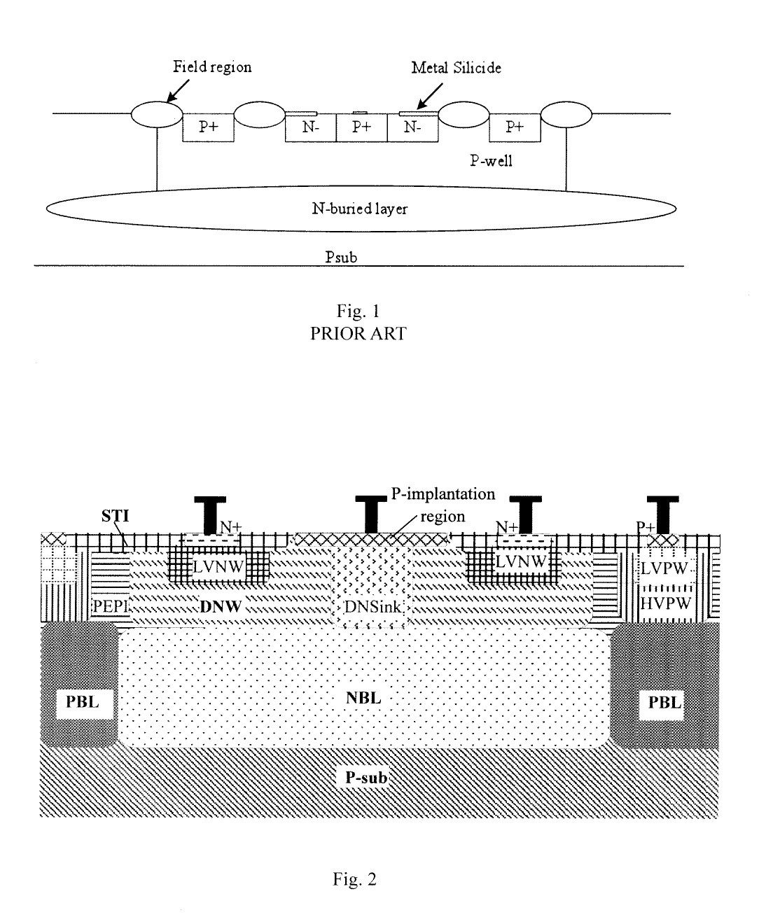

wherein, P-sub refers to P-substrate; NBL refers to N-buried layer; PBL refers to P-buried layer; DNW refers to deep N-well; HVPW refers to high voltage P-well; LVPW refers to low voltage P-well; LVNW refers to low voltage N-well; PEPI refers to P-epitaxial layer; STI refers to shallow trench isolation; DNsink refers to deep N-sinker region.

### DETAILED DESCRIPTION OF THE INVENTION

In the present invention, the vertical zener diode structure with a buried PN junction built therein is capable of improving the breakdown voltage. The vertical zener diode structure includes from the silicon surface down: a P-implantation region (formed by a shallow implantation) with a surface density in the order of 10¹⁵ atoms per square centimeter; a deep N-sinker region (formed by a deep implantation) below the P-implantation region and having a surface density in the order of 10¹⁴ atoms per square centimeter to 10¹⁵ atoms per square centimeter; the entire P-implantation region and the deep N-sinker region are formed in an epitaxial layer with a deep N-well; a concentrated N-buried layer with a surface density in the order of 10¹⁵ atoms per square centimeter can be connected to a bottom of the deep N-sinker. In a preferred embodiment, the P-implantation region has a vertical depth more than or equals to 0.2 μm. As zener breakdown occurs at a position away from the silicon surface in the vertical zener diode structure of the present invention, the problem of the drift in the zener breakdown value is improved and the reliability of the product is enhanced. The structure of the present invention has been applied in a BCD process.

The manufacturing method of the above vertical zener diode structure comprises: forming in sequence the deep N-sinker region and the P-implantation region of the zener diode in the N-well within the epitaxial layer, wherein the P-implantation region is formed on the silicon surface and is above the deep N-sinker region. The method further comprises connecting the deep N-sinker region with the N-buried layer below the N-well.

What is claimed is:

1. A zener diode structure, wherein a deep N-sinker region and a P-implantation region of the zener diode are formed in an N-well within an epitaxial layer; the P-implantation region is closer to a silicon surface than the deep N-sinker region in a vertical direction.

2. The zener diode structure according to claim 1, wherein an N-buried layer is connected to a bottom of the deep N-sinker region of the zener diode.

3. The zener diode structure according to claim 1, wherein the vertical depth of the P-implantation region is no less than 0.2 μm.

4. The zener diode structure according to claim 2, wherein the vertical depth of the P-implantation region is no less than 0.2 μm.

5. A manufacturing method of vertical zener diode, wherein a deep N-sinker region and a P-implantation region of the zener diode are formed in sequence in an N-well within an epitaxial layer; the P-implantation region is formed on a silicon surface and is above the deep N-sinker region.

6. The manufacturing method according to claim 5, wherein the deep N-sinker region is connected with an N-buried layer below the N-well.
